(19) United States
(12) Patent Application Publication
(10) Pub. No.: US 2012/0024819 A1
(43) Pub. Date: Feb. 2, 2012

(54) PLASMA PROCESSING APPARATUS AND PLASMA PROCESSING METHOD

(75) Inventor: Ryo SUEMITSU, Mie-ken (JP)

(73) Assignee: Kabushiki Kaisha Toshiba, Minato-ku (JP)

(21) Appl. No.: 13/051,727

(22) Filed: Mar. 18, 2011

(30) Foreign Application Priority Data
Jul. 30, 2010 (JP) 2010-171917

(51) Int. Cl. C23F 1/00; C23C 16/52; C23C 16/458; C23F 1/08; C23C 16/50

(52) U.S. Cl. 216/71; 156/345.43; 118/723 E; 427/569

(57) ABSTRACT

According to one embodiment, a plasma processing apparatus includes a first electrode, a second electrode, a dielectric member, and a control unit. Plasma is generated between the first electrode and the second electrode. The dielectric member is provided between the first electrode and the second electrode. The control unit is configured to change relative dielectric constant of the dielectric member in a plane crossing a first direction from the first electrode to the second electrode.

### CROSS-REFERENCE TO RELATED APPLICATIONS

This application is based upon and claims the benefit of priority from the prior Japanese Patent Application No. 2010-171917, filed on Jul. 30, 2010; the entire contents of which are incorporated herein by reference.

### FIELD

Embodiments described herein relate generally to a plasma processing apparatus and a plasma processing method.

### BACKGROUND

In manufacture of electronic devices such as semiconductor devices, for example, processing using plasma such as dry etching and CVD (Chemical Vapor Deposition) is performed.

In order to obtain high-density plasma, for example, if a frequency of excitation power is increased, plasma density at the center of a processing chamber becomes extremely higher than at the peripheral part, and in-plane distribution of the plasma density becomes large.

In order to uniformly process a substrate to be processed, plasma density uniform in a plane is desired.

### BRIEF DESCRIPTION OF THE DRAWINGS

FIG. 1 is a schematic cross-sectional view illustrating the configuration of a plasma processing apparatus according to a first embodiment;

FIGS. 2A to 2L are schematic views illustrating operations of the plasma processing apparatus according to the first embodiment;

FIG. 3 is a schematic view illustrating characteristics of a dielectric member used in the plasma processing apparatus according to the first embodiment;

FIG. 4 is a schematic view illustrating another characteristic of the dielectric member used in the plasma processing apparatus according to the first embodiment;

FIGS. 5A to 5C are schematic cross-sectional views illustrating the configuration of another plasma processing apparatus according to the first embodiment;

FIGS. 6A to 6D are schematic views illustrating another operation of the plasma processing apparatus according to the first embodiment;

FIG. 7 is a schematic cross-sectional view illustrating the configuration of another plasma processing apparatus according to the first embodiment;

FIGS. 8A to 8F are schematic views illustrating operations of another plasma processing apparatus according to the first embodiment;

FIG. 9 is a schematic cross-sectional view illustrating the configuration of another plasma processing apparatus according to the first embodiment;

FIG. 10 is a flowchart illustrating a plasma processing method according to a second embodiment;

FIG. 11 is a flowchart illustrating another plasma processing method according to the second embodiment; and

FIGS. 12A and 12B are schematic views illustrating operations of another plasma processing method according to the second embodiment.

### DETAILED DESCRIPTION

In general, according to one embodiment, a plasma processing apparatus includes a first electrode, a second electrode, a dielectric member, and a control unit. Plasma is generated between the first electrode and the second electrode. The dielectric member is provided between the first electrode and the second electrode. The control unit is configured to change relative dielectric constant of the dielectric member in a plane crossing a first direction from the first electrode to the second electrode.

Embodiments will now be described with reference to the drawings.

The drawings are schematic or conceptual; and the relationships between the thickness and width of portions, the proportional coefficients of sizes among portions, etc., are not necessarily the same as the actual values thereof. Further, the dimensions and proportional coefficients may be illustrated differently among drawings, even for identical portions.

In the specification of the application and the drawings, components similar to those described in regard to a drawing thereinabove are marked with like reference numerals, and a detailed description is omitted as appropriate.

### First Embodiment

A plasma processing apparatus according to the embodiment can be applied to any processing apparatus using plasma such as a dry etching apparatus using plasma, a film forming apparatus using plasma including a plasma CVD apparatus and the like. An example in which the plasma processing apparatus according to the embodiment will be described below. The example is applied to a dry etching apparatus using plasma. Among the dry etching apparatuses, a capacitively coupled plasma (CCP) processing apparatus will be described as an example.

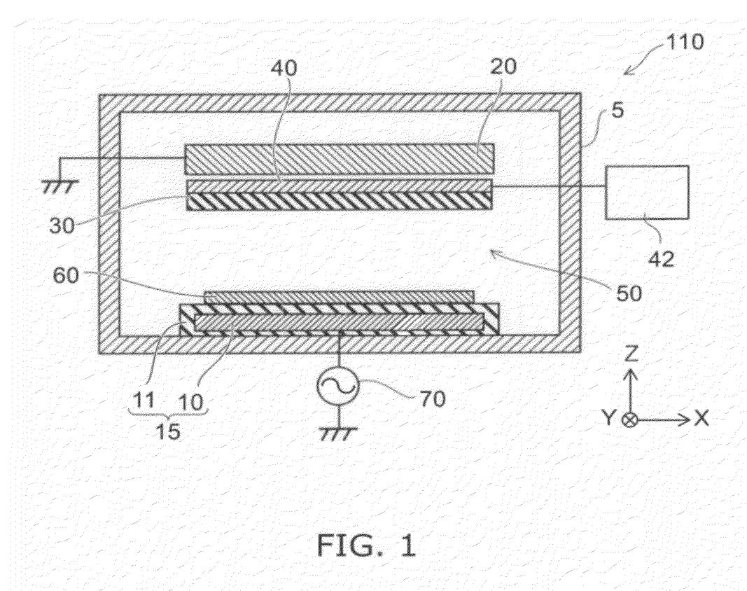

FIG. 1 is a schematic cross-sectional view illustrating the configuration of a plasma processing apparatus according to a first embodiment.

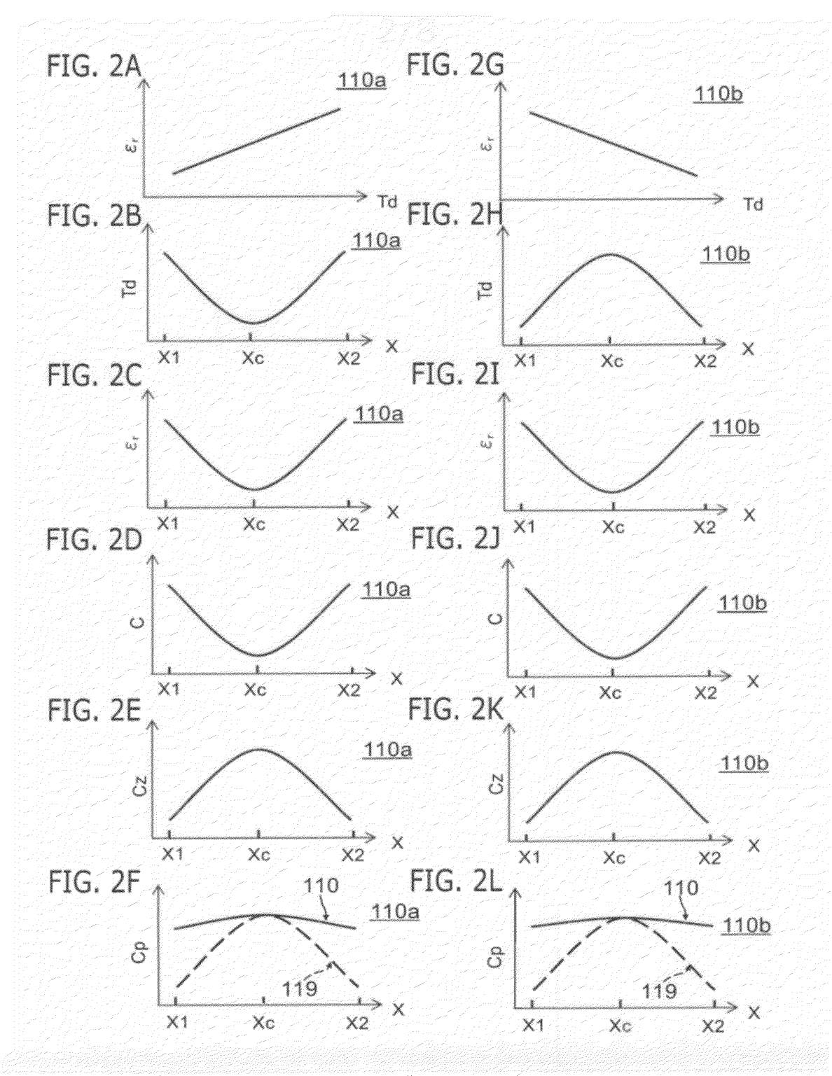

FIGS. 2A to 2L are schematic views illustrating operations of the plasma processing apparatus according to the first embodiment.

As illustrated in FIG. 1, the plasma processing apparatus 110 according to the embodiment is provided with a processing chamber 5, a first electrode 10, a second electrode 20, a dielectric member 30, and a control unit 40 (a relative dielectric constant control unit).

The processing chamber 5 is a chamber whose inside can be sealed, for example, and a wafer 60 (an object to be processed by plasma) can be contained inside.

The first electrode 10 and the second electrode 20 are provided inside the processing chamber 5. In the specific example, the first electrode 10 and the second electrode 20 are parallel plates.

The first electrode 10 is provided in the lower side in the processing chamber 5, for example. The second electrode 20 is opposed to the first electrode 10, for example. In the specific example, the second electrode 20 is disposed in the upper side in the processing chamber 5. However, arrangement of the first electrode 10 and the second electrode 20 in the processing chamber 5 is arbitrary.

In the specific example, the first electrode 10 is provided inside an ESC (Electro Static Chuck) 15. The ESC 15 has a wafer holding section 11 made of ceramic, for example, and the first electrode 10 is buried inside the wafer holding section 11. The ESC 15 absorbs the wafer 60 by an electrostatic force and holds the wafer 60.

A high-frequency power source 70 is connected to a circuit including the first electrode 10 and the second electrode 20. In the specific example, the high-frequency power source 70 is connected to the first electrode 10, and the second electrode 20 is grounded. By high-frequency power supplied from the high-frequency power source 70, plasma is generated in a space 50 between the first electrode 10 and the second electrode 20. The plasma processing apparatus 110 may include the high-frequency power source 70, or the high-frequency power source 70 may be provided separately from the plasma processing apparatus 110.

As described above, plasma is generated between the first electrode 10 and the second electrode 20.

The dielectric member 30 is provided between the first electrode 10 and the second electrode 20.

In the specific example, as described above, the second electrode 20 is provided above the first electrode 10, and the wafer 60 (an object to be processed) is disposed between the first electrode 10 and the dielectric member 30 so that plasma processing can be performed. That is, the dielectric member 30 is disposed above the position where the wafer 60 is disposed (on the side of the second electrode 20).

The control unit 40 changes relative dielectric constant of the dielectric member 30 in a plane crossing a first direction from the first electrode 10 to the second electrode 20. The control unit 40 forms in-plane distribution of the relative dielectric constant in the dielectric member 30 without changing the material of the dielectric member 30 by controlling at least one of a thermal state of the dielectric member 30 and an external force including a mechanical force applied by the dielectric member 30. As a result, the in-plane distribution of the relative dielectric constant of the dielectric member 30 can be easily controlled, and the in-plane distribution can be changed easily.

Here, the first direction from the first electrode 10 to the second electrode 20 is taken as a Z-axis direction. One direction perpendicular to the Z-axis direction is taken as an X-axis direction (second direction). A direction perpendicular to the Z-axis direction and the X-axis direction is taken as a Y-axis direction (third direction). An X-Y plane is a plane perpendicular to the Z-axis direction.

A plane crossing the Z-axis direction from the first electrode 10 to the second electrode 20 is the X-Y plane, for example. The dielectric member 30 is a structural body in a plate shape, a sheet shape, a layer shape or a film shape having a surface parallel with the X-Y plane, for example. The dielectric member 30 does not necessarily have to be planar but may be linear extending along the X-Y plane, for example (a folded linear shape, for example). In the following, explanation will be made assuming that the dielectric member 30 has a plane shape, for example (or a sheet shape, a layer shape or a film shape).

The control unit 40 changes the relative dielectric constant of the dielectric member 30 in the X-Y plane crossing the Z-axis direction, that is, in the plane of the dielectric member 30. The control unit 40 can make the relative dielectric constant of the dielectric member 30 non-uniform in the plane and form in-plane distribution of the relative dielectric constant.

For example, in a plasma processing apparatus of a reference example in which the dielectric member 30 and the control unit 40 are not provided, the plasma density at the center part of the processing chamber 5 tends to become high, while the plasma density at the peripheral part tends to become low. That is, the in-plane distribution of the plasma density is large, and the plasma density is not uniform.

On the other hand, in the plasma processing apparatus 110 according to the embodiment, in order to compensate for the distribution of the plasma density formed in the plasma processing apparatus of the reference example, the relative dielectric constant of the dielectric member 30 is made uneven in the plane, and the in-plane distribution of the relative dielectric constant is formed. As a result, non-uniformity of the plasma density in the plane is reduced.

The relative dielectric constant of the dielectric member 30 is changed in accordance with the temperature, for example. At this time, the control unit 40 changes the temperature of the dielectric member 30 in the plane of the dielectric member 30 and forms the in-plane distribution of the temperature. As a result, the in-plane distribution of the relative dielectric constant of the dielectric member 30 is formed. For the control unit 40, a heater such as a resistance wire heater and an infrared heater (including a lamp) or a cooler can be used.

As illustrated in FIG. 1, a driving section 42 is connected to the control unit 40, for example. The driving section 42 controls the control unit 40. The driving section 42 includes an electronic circuit and the like and supplies an electric current for control including an electric signal to the control unit 40. The driving section 42 may be considered as a part of the control unit 40. The plasma processing apparatus 110 may include the driving section 42, and the driving section 42 may be provided separately from the plasma processing apparatus 110.

The relative dielectric constant of the dielectric member 30 can be two cases, that is, one case having positive temperature dependency and the other case having negative temperature dependency. The temperature dependency depends on the type of the material used as the dielectric member 30, a temperature range and the like.

First, the case in which the relative dielectric constant of the dielectric member 30 has positive temperature dependency will be described below.

FIG. 2A is a graph schematically illustrating the temperature characteristic of the dielectric member 30. That is, the horizontal axis in the figure indicates a temperature Td of the dielectric member 30, and the vertical axis indicates relative dielectric constant εᵣ of the dielectric member 30.

FIGS. 2B and 2C schematically illustrate a control operation of the control unit 40. The horizontal axes in these figures indicate positions along the X-axis direction. A position Xc corresponds to the position at the center of the processing chamber 5, for example, a position X1 corresponds to a position at one end of a processing region of the processing chamber 5, and a position X2 corresponds to a position of the other end. The vertical axis in FIG. 2B indicates the temperature Td of the dielectric member 30 controlled by the control unit 40. The vertical axis in FIG. 2C is the relative dielectric constant εᵣ of the dielectric member 30.

FIGS. 2D to 2F schematically illustrate states of the plasma processing apparatus 110 obtained by the control operation of the control unit 40. The horizontal axes in these figures indicate positions in the X-axis direction. The vertical axis in FIG. 2D indicates capacitance C between the first electrode 10 and the second electrode 20. The vertical axis in FIG. 2E indicates impedance Cz between the first electrode 10 and the second electrode 20. The vertical axis in FIG. 2F indicates plasma density Cp generated between the first electrode 10 and the second electrode 20. In FIG. 2F, in addition to the characteristics in the plasma processing apparatus 110 according to the embodiment illustrated by a solid line, the characteristics of a plasma processing apparatus 119 as the above reference example are also illustrated by a broken line.

As illustrated in FIG. 2A, the relative dielectric constant εᵣ of the dielectric member 30 is low when the temperature Td is low and high when the temperature Td is high. That is, the relative dielectric constant εᵣ has positive temperature dependency 110a.

At this time, as illustrated in FIG. 2B, the temperature Td of the dielectric member 30 is controlled higher at the outer positions X1 and X2 than at the center position Xc by the control unit 40.

As a result, as illustrated in FIG. 2C, the relative dielectric constant εᵣ of the dielectric member 30 becomes higher at the outer positions X1 and X2 than the center position Xc.

That is, the control unit 40 makes the relative dielectric constant of outer portions of the dielectric member 30 higher than the relative dielectric constant of a portion at the center in the X-Y plane (a plane orthogonal to the Z-axis direction) in the dielectric member 30. The outer portions are located on the outer sides from the center portion in the X-Y plane in the dielectric member 30.

The capacitance C between the first electrode 10 and the second electrode 20 is expressed as C=ε₀·εᵣ·S/d. Here, ε₀ denotes dielectric constant of vacuum, S denotes an area of a portion where the first electrode 10 and the second electrode 20 oppose each other, and d denotes a distance between the first electrode 10 and the second electrode 20.

Therefore, as illustrated in FIG. 2D, the capacitance C between the first electrode 10 and the second electrode 20 becomes larger at the outer positions X1 and X2 than at the center position Xc.

Impedance Cz between the first electrode 10 and the second electrode 20 is expressed as |Cz|=1/(ωC). Here, ω is an angular frequency of high-frequency power supplied by the high-frequency power source 70 (ω=2πf when a frequency is f).

Therefore, as illustrated in FIG. 2E, the impedance Cz between the first electrode 10 and the second electrode 20 becomes smaller at the outer positions X1 and X2 than at the center position Xc.

If the impedance Cz is small, an ion current is increased, and plasma density Cp is increased. As a result, as illustrated by a solid line in FIG. 2F, the plasma density Cp is made uniform at the center position Xc and at the outer positions X1 and X2.

That is, as indicated by a broken line in FIG. 2F, in the plasma processing apparatus 119 of the reference example in which the dielectric member 30 and the control unit 40 are not provided, the plasma density Cp is extremely higher at the center position Xc than at the outer positions X1 and X2.

On the other hand, in the plasma processing apparatus 110 according to the embodiment, by setting the relative dielectric constant εᵣ of the dielectric member 30 higher on the outside than at the center portion, the in-plane distribution of the plasma density Cp is compensated, and non-uniformity of the plasma density Cp can be reduced. As a result, according to the embodiment, a plasma processing apparatus having excellent controllability of the plasma density Cp can be provided.

In the above, the characteristics along the X-axis direction have been described, but the same applies to the characteristics along the Y-axis direction. That is, according to the embodiment, the characteristics of the plasma density Cp in the X-Y plane can be controlled.

By using the plasma processing apparatus 110 according to the embodiment, non-uniformity of the plasma density Cp in the plane can be reduced, and thus, a silicon oxide film of the wafer 60 can be uniformly etched in the plane, for example.

Subsequently, a case in which the relative dielectric constant εᵣ of the dielectric member 30 has negative temperature dependency will be described.

FIG. 2G is a graph schematically illustrating the temperature characteristics of the dielectric member 30. FIGS. 2H and 2I schematically illustrate the control operation of the control unit 40. FIGS. 2J to 2L schematically illustrate states of the plasma processing apparatus 110 obtained by the control operation of the control unit 40.

As illustrated in FIG. 2G, the relative dielectric constant εᵣ of the dielectric member 30 is high when the temperature Td is low and low when the temperature Td is high. That is, the relative dielectric constant εᵣ has negative temperature dependency 110b.

At this time, as illustrated in FIG. 2H, the temperature Td of the dielectric member 30 is controlled lower at the outer positions X1 and X2 than at the center position Xc by the control unit 40.

As a result, as illustrated in FIG. 2I, the relative dielectric constant εᵣ of the dielectric member 30 becomes higher at the outer positions X1 and X2 than at the center position Xc. As a result, as illustrated in FIG. 2J, the capacitance C between the first electrode 10 and the second electrode 20 becomes larger at the outer positions X1 and X2 than at the center position Xc. And as illustrated in FIG. 2K, the impedance Cz between the first electrode 10 and the second electrode 20 becomes smaller at the outer positions X1 and X2 than at the center position Xc. As a result, as illustrated by a solid line in FIG. 2L, the plasma density Cp is made uniform at the center position Xc and at the positions X1 and X2.

Then, the characteristics similar to those along the X-axis direction described above can be also obtained in the X-Y plane.

As described above, even if the relative dielectric constant εᵣ has the negative temperature dependency 110b, the in-plane distribution of the plasma density Cp is compensated, and non-uniformity of the plasma density Cp can be reduced by the plasma processing apparatus 110 according to the embodiment.

The in-plane distribution of the plasma density Cp can be measured by Langmuir probe or the like, for example.

For the dielectric member 30, any material whose relative dielectric constant is changed by an external stimulation can be used. For the dielectric member 30, a ferroelectric material such as barium titanate (TiBaO₃), lead zirconate (PbZrO₃), calcium titanate (CaTiO₃), strontium titanate (SrTiO₃), tri-glycine sulfate (TGS) and the like can be used.

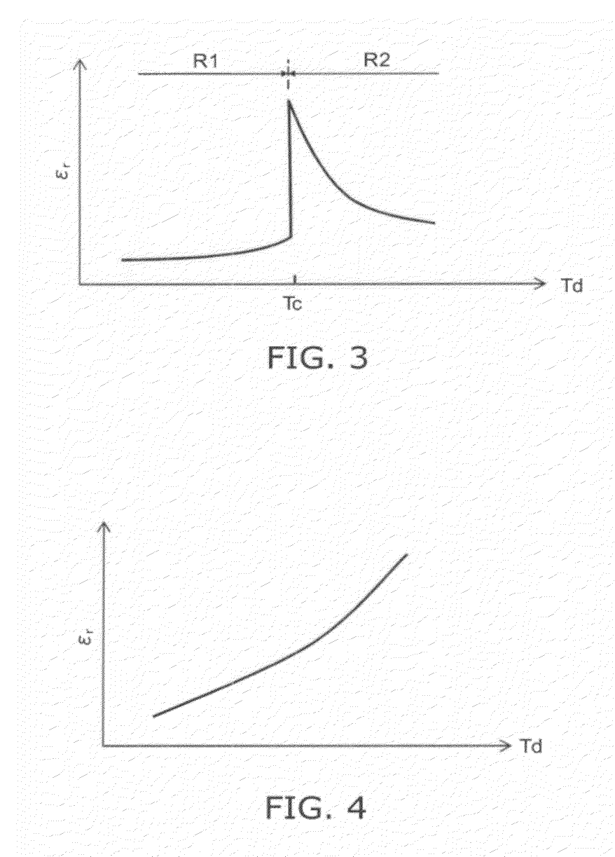

FIG. 3 is a schematic view illustrating characteristics of a dielectric member used in the plasma processing apparatus according to the first embodiment.

That is, FIG. 3 is a graph illustrating the characteristic of the dielectric member 30 when a ferroelectric material such as barium titanate is used for the dielectric member 30. The horizontal axis indicates the temperature Td and the vertical axis indicates the relative dielectric constant εᵣ.

As illustrated in FIG. 3, the relative dielectric constant εᵣ changes greatly between a temperature lower than a phase transition temperature Tc (Curie temperature, for example) and a temperature higher than that. In a temperature region R1 lower than the phase transition temperature Tc (a temperature region corresponding to a ferroelectric phase), the relative dielectric constant εᵣ has the positive temperature dependency. If the temperature is increased from a temperature lower than the phase transition temperature Tc to a temperature higher than that, the relative dielectric constant εᵣ rapidly increases at the phase transition temperature Tc. In a temperature zone R2 higher than the phase transition temperature Tc (a temperature region corresponding to a paraelectric phase), the relative dielectric constant εᵣ has the negative temperature dependency.

In the embodiment, the temperature Td of the dielectric member 30 may be controlled in a range of the temperature region R1 having the positive temperature dependency. In addition, the temperature Td of the dielectric member 30 may be controlled in a range of the temperature region R2 having the negative temperature dependency. Moreover, the temperature Td of the dielectric member 30 may be controlled in a temperature region including the temperature region R1 and the temperature region R2.

For the dielectric member 30, an organic material such as a polyamide resin, for example, may be used.

FIG. 4 is a schematic view illustrating another characteristic of the dielectric member used in the plasma processing apparatus according to the first embodiment.

That is, FIG. 4 is a graph illustrating the characteristic of the dielectric member 30 when a polyamide resin is used for the dielectric member 30.

As illustrated in FIG. 4, in this case, the relative dielectric constant εᵣ has positive temperature dependency.

As described above, for the dielectric member 30, any material, whether it is inorganic or organic, including a ferroelectric material and a paraelectric material can be used. On the basis of the temperature dependency of the material, the control unit 40 changes the temperature of the dielectric member 30 in the plane of the dielectric member 30 and changes the relative dielectric constant εᵣ of the dielectric member 30 in the plane of the dielectric member 30.

In this embodiment, since the relative dielectric constant εᵣ of the dielectric member 30 is changed in the plane by changing the temperature of the dielectric member 30 in the plane, which is easy, and controllability of the relative dielectric constant εᵣ is high.

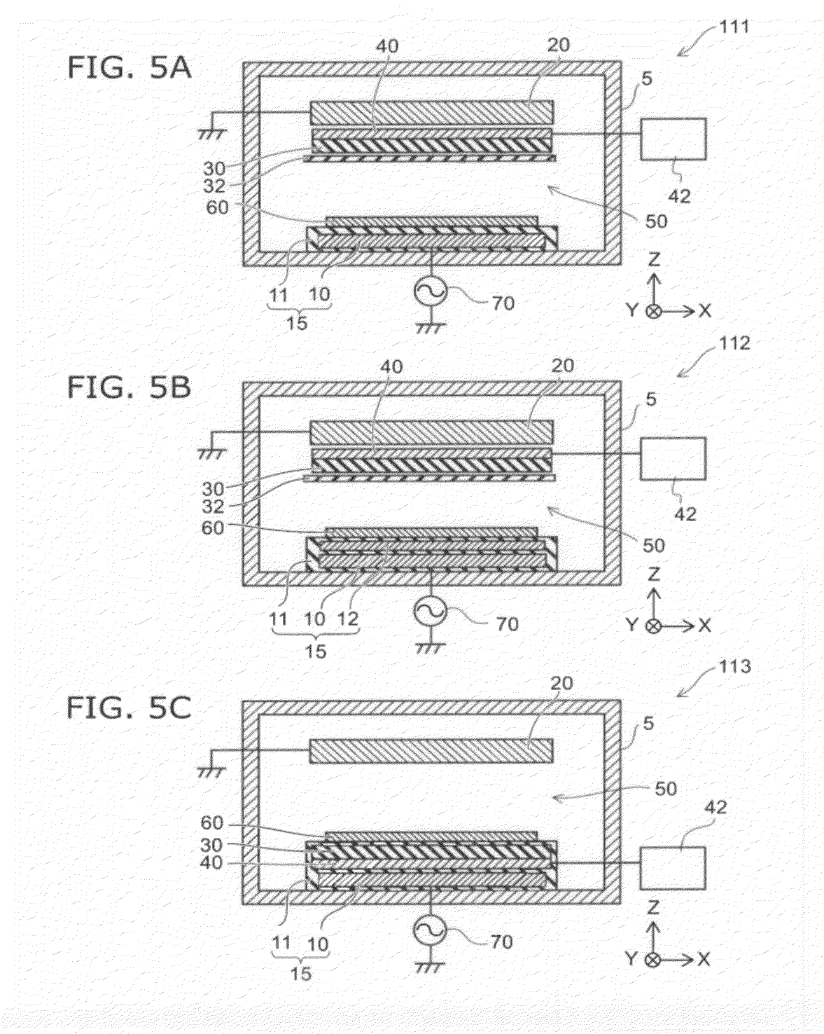

FIGS. 5A to 5C are schematic cross-sectional views illustrating the configuration of another plasma processing apparatus according to the first embodiment.

As illustrated in FIG. 5A, a plasma processing apparatus 111 is further provided with a cover member 32 provided between the dielectric member 30 and the first electrode 10. The cover member 32 is provided between the dielectric member 30 and a position where the wafer 60 is installed. The cover member 32 is provided between the space 50 in which plasma is generated and the dielectric member 30. The cover member 32 has stability against the generated plasma, for example. By providing the cover member 32, damage on the dielectric member 30 by the plasma can be suppressed.

As illustrated in FIG. 5B, a plasma processing apparatus 112 is further provided with a temperature control section 12 provided between the first electrode 10 and the dielectric member 30 and configured to control a temperature of the wafer 60 (an object to be processed). In the specific example, the temperature control section 12 is buried in the wafer holding section 11 of the ESC 15.

For the temperature control section 12, a heater, for example, is used. By the temperature control section 12, the temperature of the wafer 60 is changed in the plane of the wafer 60. The temperature at the center part of the wafer 60 is set low, for example, and the temperature is set to increase along a direction from the center part to the peripheral part.

The processing using the plasma applied to the wafer 60 (at least one of etching or film formation, for example) has temperature dependency. If the surface temperature of the wafer 60 is high, for example, the etching speed increases compared with the case of a low temperature. That is, reactivity on the surface of the wafer 60 depends on a temperature. By using this characteristic, uniformity in processing in the plane of the wafer 60 can be further improved.

That is, by using both the effect of control on the plasma density Cp by controlling the relative dielectric constant εᵣ of the dielectric member 30 in the plane and control of reactivity in the plane of the wafer 60 by controlling the temperature of the wafer 60 in the plane, plasma processing with higher controllability can be realized.

As illustrated in FIG. 5C, in a plasma processing apparatus 113, the dielectric member 30 and the control unit 40 are provided between the first electrode 10 and the position where the wafer 60 (an object to be processed) is disposed. In the specific example, the dielectric member 30 and the control unit 40 are buried in the wafer holding section 11 of the ESC 15. In this case as well, by controlling the relative dielectric constant εᵣ of the dielectric member 30, the plasma density Cp can be controlled, and non-uniformity of the plasma density Cp can be reduced. As described above, in this example, the second electrode 20 is provided above the first electrode 10, the dielectric member 30 is provided on the first electrode 10, and the wafer 60 is disposed between the dielectric member 30 and the second electrode 20 and then, the processing is performed.

As described above, the dielectric member 30 (and the control unit 40) can be disposed at any place between the first electrode 10 and the second electrode 20 where plasma is generated.

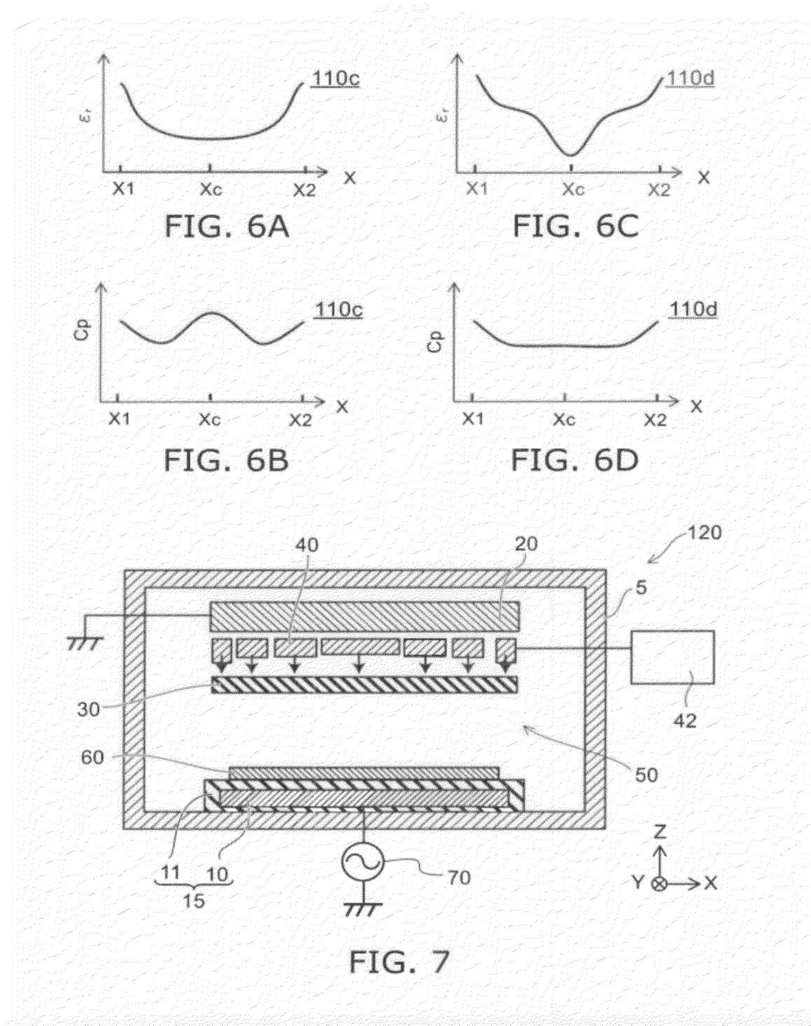

FIGS. 6A to 6D are schematic views illustrating another operation of the plasma processing apparatus according to the first embodiment.

FIG. 6A illustrates in-plane distribution 110c of the relative dielectric constant εᵣ of the dielectric member 30 controlled by the control unit 40, and FIG. 6B illustrates the plasma density Cp corresponding to the in-plane distribution 110c. FIG. 6C illustrates another in-plane distribution 110d of the relative dielectric constant εᵣ of the dielectric member 30 controlled by the control unit 40, and FIG. 6D illustrates the plasma density Cp corresponding to the in-plane distribution 110d.

As illustrated in FIG. 6A, in the in-plane distribution 110c, the relative dielectric constant εᵣ is set low in a wide range including the center position Xc as compared with the example illustrated in FIG. 2C. And the relative dielectric constant εᵣ is controlled so that the relative dielectric constant εᵣ is increased rapidly in the vicinity of the outer positions X1 and X2.

In this case, as illustrated in FIG. 6B, the plasma density Cp is high in the vicinities of the center position Xc and the outer positions X1 and X2. And it is low in regions between the position Xc and the positions X1 and X2.

As illustrated in FIG. 6C, in the in-plane distribution 110d, a change rate of the relative dielectric constant εᵣ is high in the vicinities of the center position Xc and the outer positions X1 and X2. And it is low in an intermediate portion between the position Xc and the position X1 and an intermediate portion between the position Xc and the position X2.

In this case, as illustrated in FIG. 6D, the plasma density Cp is relatively uniform in a region including the center position Xc and high in the vicinities of the outer positions X1 and X2.

As described above, the plasma density Cp is not only controlled uniformly in the X-Y plane but also can be controlled to any characteristic as illustrated in FIGS. 6B and 6D. If workability of the wafer 60 has distribution in the plane of the wafer 60, for example, more desirable processing can be performed by controlling the plasma density Cp in the plane to a desired characteristic.

FIG. 7 is a schematic cross-sectional view illustrating the configuration of another plasma processing apparatus according to the first embodiment.

As illustrated in FIG. 7, in another plasma processing apparatus 120 according to the embodiment, the control unit 40 changes a pressure to be applied to the dielectric member 30 in a plane crossing the Z-axis direction (the X-Y plane, for example, and in the plane of the dielectric member 30).

For example, the control unit 40 has a plurality of pressure application portions divided in the X-Y plane. The pressure by the pressure application portions are applied to the dielectric member 30. For the pressure application portion, a member that is deformed mechanically or a member that is deformed on the basis of volume expansion and contraction by a signal from the outside, for example, is used. That is, the control unit 40 includes the pressure application portions that can apply pressures different from each other in the plane of the dielectric member 30 to the dielectric member 30.

For the dielectric member 30, a piezoelectric body, for example, whose relative dielectric constant εᵣ is changed by the pressure applied from the outside is used. On the basis of a relationship between a structure of the piezoelectric body (crystal orientation, for example) and a direction of the pressure to be applied, the relative dielectric constant εᵣ might have positive pressure dependency or the relative dielectric constant εᵣ might have negative pressure dependency.

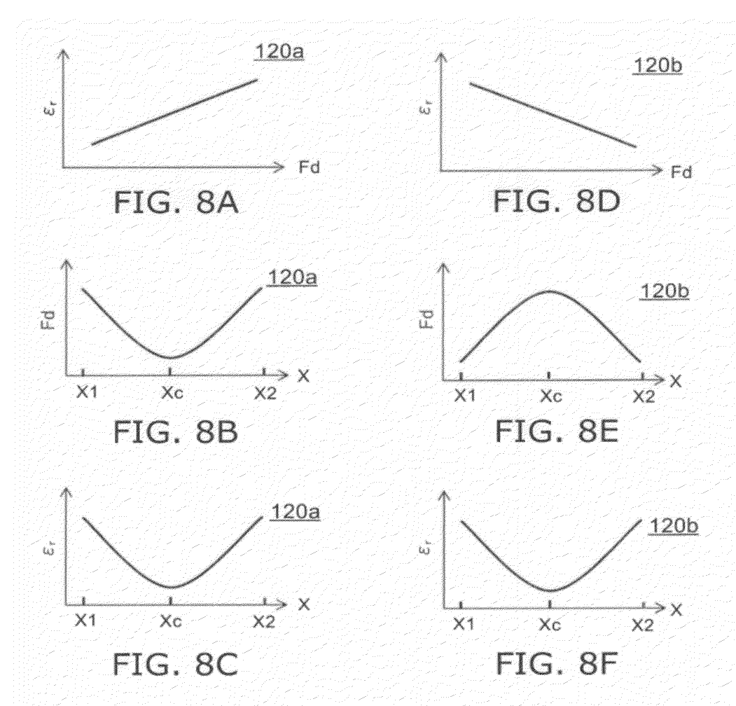

FIGS. 8A to 8F are schematic views illustrating operations of another plasma processing apparatus according to the first embodiment.

FIG. 8A is a graph schematically illustrating the pressure dependency (positive dependency) of the relative dielectric constant εᵣ of the dielectric member 30. FIGS. 8B and 8C schematically illustrate the control operation of the control unit 40. The vertical axis in FIG. 8B indicates a pressure Fd applied to the dielectric member 30 controlled by the control unit 40. The vertical axis in FIG. 8C is the relative dielectric constant εᵣ of the dielectric member 30.

As illustrated in FIG. 8A, the relative dielectric constant εᵣ of the dielectric member 30 is low when the pressure Fd is low and high when the pressure Fd is high. That is, the relative dielectric constant εᵣ has positive pressure dependency 120a.

At this time, as illustrated in FIG. 8B, the pressure Fd applied to the dielectric member 30 by the unit 40 is controlled so as to be larger at the outer positions X1 and X2 than at the center position Xc.

As a result, as illustrated in FIG. 8C, the relative dielectric constant εᵣ of the dielectric member 30 becomes higher at the outer positions X1 and X2 than at the center position Xc.

As a result, as already described, the capacitance C becomes larger at the outer positions X1 and X2 than at the center position Xc, and the impedance Cz becomes smaller at the outer positions x1 and X2 than at the center position Xc and as a result, the plasma density Cp is made uniform in the plane.

FIG. 8D is a graph schematically illustrating pressure dependency (negative dependency) of the relative dielectric constant εᵣ of the dielectric member 30. FIGS. 8E and 8F schematically illustrate the control operation of the control unit 40.

As illustrated in FIG. 8D, the relative dielectric constant εᵣ of the dielectric member 30 is high when the pressure Fd is low and low when the pressure Fd is high. That is, the relative dielectric constant εᵣ has negative pressure dependency 120b.

At this time, as illustrated in FIG. 8E, the pressure Fd applied to the dielectric member 30 by the control unit 40 is controlled so as to be smaller at the outer positions X1 and X2 than at the center position Xc.

As a result, as illustrated in FIG. 8F, the relative dielectric constant εᵣ of the dielectric member 30 becomes higher at the outer positions X1 and X2 than at the center position Xc.

In this case, the plasma density Cp is also made uniform in the plane.

As described above, also in the plasma processing apparatus 120 that controls the relative dielectric constant εᵣ of the dielectric member 30 by the pressure Fd applied to the dielectric member 30, the plasma density Cp can be made uniform in the plane.

Moreover, as described in relation with FIGS. 6A to 6D, according to the plasma processing apparatus 120, the plasma density Cp can be controlled to any characteristic. Thereby, more desirable processing can be realized.

Also, in the plasma processing apparatus 120, the cover member 32 described in relation with FIG. 5A and/or the temperature control section 12 described in relation with FIG. 5B may be further provided. Also, as described in relation with FIG. 5C, the dielectric member 30 and the control unit 40 may be provided between the first electrode 10 and the position where the wafer 60 (an object to be processed) is disposed. For example, the dielectric member 30 and the control unit 40 that controls the pressure may be buried in the wafer holding section 11 of the ESC 15.

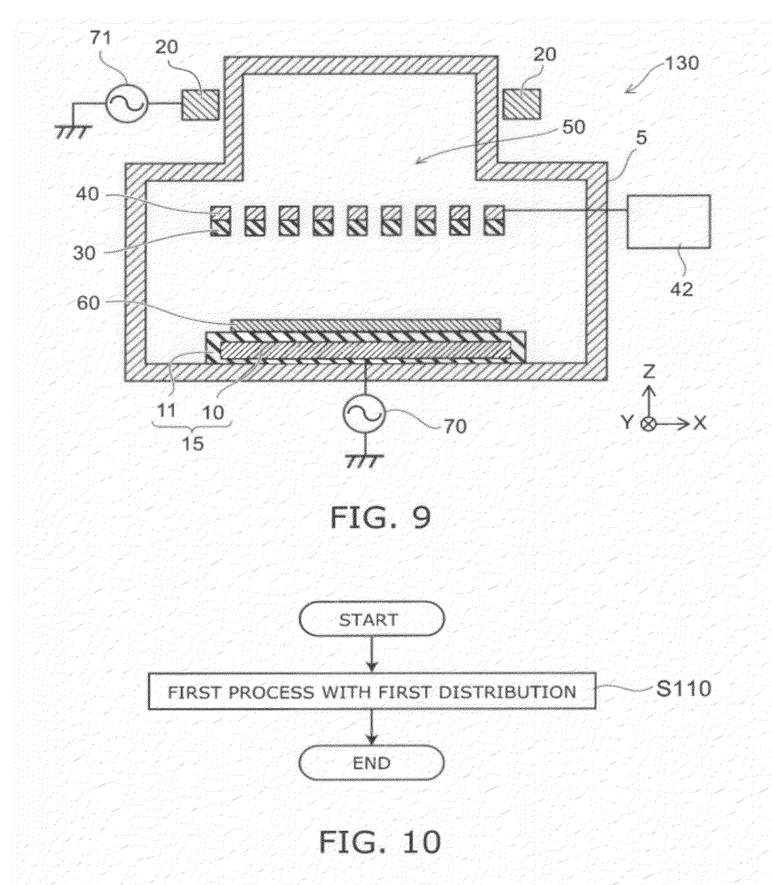

FIG. 9 is a schematic cross-sectional view illustrating the configuration of another plasma processing apparatus according to the first embodiment.

As illustrated in FIG. 9, a plasma processing apparatus 130 according to the embodiment is an inductively coupled plasma processing apparatus.

In this case, the first electrode 10 is provided inside the processing chamber 5, and the second electrode 20 is provided outside the processing chamber 5. The second electrode 20 surrounds the upper part of the processing chamber 5 in the X-Y plane

A high-frequency power source 71 is connected to the second electrode 20. The second electrode 20 functions as an antenna.

By high-frequency power supplied to the second electrode 20, plasma is generated in the space 50 between the first electrode 10 and the second electrode 20.

In this case as well, the dielectric member 30 is provided between the first electrode 10 and the second electrode 20. And, the control unit 40 that changes the relative dielectric constant of the dielectric member 30 in the plane crossing the direction from the first electrode 10 to the second electrode 20 is provided.

In this specific example, the dielectric member 30 and the control unit 40 are disposed above the position where the wafer 60 is disposed (on the side of the second electrode 20). But in the plasma processing apparatus 113, the dielectric member 30 and the control unit 40 may be provided between the first electrode 10 and the position where the wafer 60 is disposed.

In this specific example, the dielectric member 30 and the control unit 40 have linear shapes extending in the X-Y plane

In the ICP type plasma processing apparatus, too, by changing the relative dielectric constant εᵣ of the dielectric member 30 by the control unit 40 in the plane of the dielectric member 30, the plasma density Cp can be brought into a desirable state (uniform in the plane, for example).

### Second Embodiment

FIG. 10 is a flowchart illustrating a plasma processing method according to a second embodiment.

As illustrated in FIG. 10, the plasma processing method according to the embodiment is provided with a first process (Step S110). In the first process, a first plasma is generated in the space 50 between the first electrode 10 and the second electrode 20, and the wafer 60 (an object to be processed) is processed by the first plasma. The first plasma is generated with a first distribution of the relative dielectric constant εᵣ of the dielectric member 30, which is provided between the first electrode 10 and the second electrode 20. In the first distribution, the relative dielectric constant is changed in a plane crossing the direction from the first electrode 10 to the second electrode 20.

For example, by changing at least one of the temperature of the dielectric member 30 and the pressure applied to the dielectric member 30 in the plane of the dielectric member 30, the relative dielectric constant εᵣ of the dielectric member 30 is changed in the plane of the dielectric member 30. As a result, the density Cp of the generated plasma can be controlled to a desired state, and desired processing can be realized. For example, the plasma density Cp can be made uniform in the plane, and uniform processing in the plane can be realized.

The plasma processing method according to the embodiment can be applied to processing including at least one of etching using plasma and film formation.

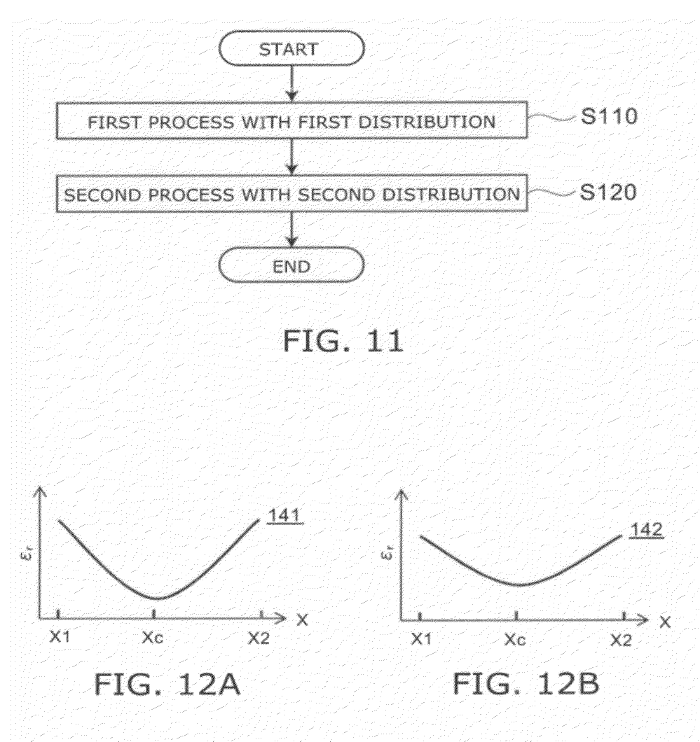

FIG. 11 is a flowchart illustrating another plasma processing method according to a second embodiment.

As illustrated in FIG. 11, a plasma processing according to the embodiment is further provided with a second process (Step S120). In the second process, a second plasma is generated in the space 50, and the wafer 60 is processed by the second plasma. The second plasma is generated with a second distribution of the relative dielectric constant εᵣ of the dielectric member 30. The second distribution is different from the first distribution.

That is, in this processing method, in the first process and the second process, the in-plane distribution of the relative dielectric constant εᵣ of the dielectric member 30 is made different from each other, and the processing is performed.

FIGS. 12A and 12B are schematic views illustrating operations of another plasma processing method according to the second embodiment.

That is, FIG. 12A illustrates the in-plane distribution of the relative dielectric constant εᵣ in the first process (first distribution 141), and FIG. 12B illustrates the in-plane distribution of the relative dielectric constant εᵣ in the second process (second distribution 142). In these figures, the horizontal axis is the position along the X-axis direction and the vertical axis is the relative dielectric constant εᵣ of the dielectric member 30.

As illustrated in FIGS. 12A and 12B, the second distribution 142 of the relative dielectric constant εᵣ in the second process is different from the first distribution 141 of the relative dielectric constant εᵣ in the first process. By making the in-plane distribution of the relative dielectric constant εᵣ different from each other as above, the in-plane distribution of the plasma density Cp can be made different from each other. As a result, processing in a more desirable state can be realized.

For example, the first process and the second process may be initial process and second-half process in one plasma processing. This method is adopted if a more desirable processing result can be obtained by changing the distribution of the plasma density Cp between the initial processing and the second-half processing.

Also, it may be configured that the first process is processing for the first wafer and the second process is processing for another wafer 60. For example, a history of processing is different between the first wafer 60 and the second wafer 60. Also, the configuration (material, thickness, pattern and the like of a metal layer, a semiconductor layer and an insulating layer) is different between the first wafer 60 and the second wafer 60. At this time, processing can be performed under a plasma condition suitable for the respective wafers 60, and a more desirable processing can be performed. Thus, process flexibility can be improved.

The plasma processing method according to the embodiment can be put into practice using any of the plasma processing apparatuses described in relation with the first embodiment or a plasma processing apparatus of their variation, for example. According to the plasma processing apparatus according to the embodiment, the distribution of the relative dielectric constant εᵣ in the dielectric member 30 can be easily controlled by the control unit 40 without changing the material of the dielectric member 30. Plasma conditions different between the first process and the second process can be created easily.

According to the plasma processing apparatus and the plasma processing method according to the embodiment, the plasma density Cp can be controlled to a desired state, for example, which is particularly effective in obtaining high in-plane uniformity in plasma with a large area. And the distribution of the plasma density Cp can be changed in the process or between processes, for example, and more desirable processing can be performed.

The plasma processing apparatus and the plasma processing method according to the embodiment can be applied to processing of an object to be processed having a 300 mm size, processing of an object to be processed having a 450 mm size and processing of a next-generation object to be processed having a larger size, for example. The apparatus and the method can be applied to any processing such as processing including etching and film formation on a silicon substrate (wafer), a substrate of SOI (Silicon On Insulator) and a substrate of a compound semiconductor, processing of amorphous silicon film formation for solar cell with a large area, processing of etching and film formation in flat panel displays with a large area and the like.

As described above, according to the embodiment, a plasma processing apparatus and a plasma processing method with excellent controllability of the plasma density are provided.

The embodiments of the invention have been described above by referring to the specific examples. However, the embodiments of the invention are not limited by these specific examples. For example, regarding the specific configuration of each element such as the first electrode, the second electrode, the dielectric member, the control unit, the processing chamber, the ESC, the wafer holding section, the temperature control section, the cover member, the driving section, the high-frequency power source and the like included in the plasma processing apparatus are contained in the range of the invention as long as those skilled in the art can carry out the invention similarly and obtain the similar advantages by making selection from a known range as appropriate.

Also, those obtained by combining any two or more or elements of each specific example in a technically feasible range are also contained in the range of the invention as long as the gist of the invention is contained.

And all the other plasma processing apparatuses and plasma processing methods that can be carried out by those skilled in the art with appropriate design change on the basis of the plasma processing apparatus and the plasma processing method described above as the embodiments of the invention also belongs to the range of the invention as long as the gist of the invention is contained.

The other variations and modifications in the scope of the idea of the invention that could have been easily conceived of by those skilled in the art are also understood to belong to the range of the invention.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modification as would fall within the scope and spirit of the inventions.

What is claimed is:

1. A plasma processing apparatus comprising:
a first electrode;
a second electrode, plasma being generated between the first electrode and the second electrode;
a dielectric member provided between the first electrode and the second electrode; and
a control unit configured to change relative dielectric constant of the dielectric member in a plane crossing a first direction from the first electrode to the second electrode.

2. The apparatus according to claim 1, wherein the control unit changes at least one of a temperature of the dielectric member and a pressure applied to the dielectric member in the plane.

3. The apparatus according to claim 1, wherein
the second electrode is provided above the first electrode; and
a processing is performed to an object to be processed which is disposed between the first electrode and the dielectric member.

4. The apparatus according to claim 1, wherein the control unit makes the relative dielectric constant of the dielectric member non-uniform in the plane so as to compensate distribution of plasma density of the plasma.

5. The apparatus according to claim 1, wherein the control unit makes the relative dielectric constant of an outer portion of the dielectric member higher than the relative dielectric constant of a center portion of the dielectric member, the center portion being located at a center of the dielectric member in an orthogonal plane to the first direction, the outer portion being located outer than the center portion in the orthogonal plane.

6. The apparatus according to claim 1, wherein
the relative dielectric constant of the dielectric member has positive temperature dependency; and
the control unit makes a temperature of an outer portion of the dielectric member higher than a temperature of a center portion of the dielectric member, the center portion being located at a center of the dielectric member in an orthogonal plane to the first direction, the outer portion being located outer than the center portion in the orthogonal plane.

7. The apparatus according to claim 1, wherein
the relative dielectric constant of the dielectric member has negative temperature dependency; and
the control unit makes a temperature of an outer portion of the dielectric member lower than a temperature of a center portion of the dielectric member, the center portion being located at a center of the dielectric member in an orthogonal plane to the first direction, the outer portion being located outer than the center portion in the orthogonal plane.

8. The apparatus according to claim 1, wherein
the control unit changes a temperature of the dielectric member in a plane of the dielectric member; and
the control unit includes at least one of a heater and a cooler.

9. The apparatus according to claim 1, wherein the dielectric member includes a ferroelectric material.

10. The apparatus according to claim 1, wherein the dielectric member includes at least one of barium titanate (TiBaO₃), lead zirconate (PbZrO₃), calcium titanate (CaTiO₃), strontium titanate (SrTiO₃), and tri-glycine sulfate (TGS).

11. The apparatus according to claim 1, further comprising:
a processing chamber,
the first electrode, the second electrode, the dielectric member, and the control unit being disposed inside the processing chamber; and the processing chamber being capable of containing an object to be processed by the plasma.

12. The apparatus according to claim 1, further comprising:
an electro static chuck configured to hold an object to be processed by the plasma,
the first electrode being provided inside the electro static chuck.

13. The apparatus according to claim 3, further comprising:
a cover member provided between the dielectric member and the first electrode.

14. The apparatus according to claim 1, further comprising:
an electro static chuck configured to hold an object to be processed by the plasma; and
a temperature control section provided inside the electro static chuck and configured to control a temperature of the object.

15. The apparatus according to claim 1, wherein
the second electrode is provided above the first electrode;
the dielectric member is provided above the first electrode; and
a processing is performed to an object to be processed which is disposed between the dielectric member and the second electrode.

16. The apparatus according to claim 1, wherein
the control unit changes a pressure applied to the dielectric member in a plane of the dielectric member; and
the control unit includes pressure application portions capable of applying pressures to the dielectric member, the pressures being different from each other in the plane of the dielectric member.

17. A plasma processing method comprising:
a first process including generating a first plasma in a space between a first electrode and a second electrode and processing an object to be processed by the first plasma,
the first plasma being generated with a first distribution of relative dielectric constant of a dielectric member provided between the first electrode and the second electrode, the relative dielectric constant being changed in a plane crossing a first direction from the first electrode to the second electrode in the first distribution.

18. The method according to claim 17, further comprising:
a second process including generating a second plasma in the space and processing an object to be processed by the second plasma,
the second plasma being generated with a second distribution of the relative dielectric constant of the dielectric member,
the second distribution being different from the first distribution.

19. The method according to claim 17, wherein the first distribution is configured to compensate distribution of plasma density of plasma generated between the first electrode and the second electrode.

20. The method according to claim 17, wherein the first distribution includes a distribution having the relative dielectric constant in an outer portion of the dielectric member higher than the relative dielectric constant in a center portion of the dielectric member, the center portion being located at a center of the dielectric member in an orthogonal plane to the first direction, and the outer portion being located outer than the center portion in the orthogonal plane.
